(19) United States
(12) Patent Application Publication
(10) Pub. No.: US 2020/0343889 A1
(43) Pub. Date: Oct. 29, 2020

(54) FIELD-EFFECT TRANSISTOR SWITCH

(71) Applicant: SKYWORKS SOLUTIONS, INC., Woburn, MA (US)

(72) Inventor: Thomas William ARELL, Bedminster, NJ (US)

(21) Appl. No.: 16/858,590

(22) Filed: Apr. 25, 2020

Related U.S. Application Data
(60) Provisional application No. 62/839,139, filed on Apr. 26, 2019.

(51) Int. Cl. H03K 17/687; H03K 17/693; H03K 17/10; H03K 17/12; H03K 17/16

(52) U.S. Cl. CPC H03K 17/6871; H03K 17/693; H03K 17/161; H03K 17/122; H03K 17/102

(57) ABSTRACT

A circuit comprises a first field-effect transistor (FET) having a first gate, a first source, and a first drain, a first resistor, a first voltage generator, a second FET having a second gate, a second source, and a second drain, and coupling circuitry configured to couple the first resistor to the first gate, the first voltage generator to the first resistor and ground, and the second FET in parallel with the first resistor.

### CROSS-REFERENCE TO RELATED APPLICATION

This application claims priority to U.S. Provisional Application No. 62/839,139 filed Apr. 26, 2019, entitled IMPROVED FIELD-EFFECT TRANSISTOR SWITCH, the disclosure of which is hereby expressly incorporated by reference herein in its respective entirety.

### BACKGROUND

The present disclosure relates to field-effect transistors, related devices, and related methods for radio-frequency (RF) applications.

Figures of merit for a field-effect transistor switch process include off-capacitance and on-resistance. There is a trade-off between insertion loss, which is dominated by the field-effect transistor on-resistance, and the isolation, which is dominated by the off-capacitance.

### SUMMARY

In accordance with some implementations, the present disclosure relates to a circuit comprising a first field-effect transistor (FET) having a first gate, a first source, and a first drain, a first resistor, a first voltage generator, a second FET having a second gate, a second source, and a second drain, and coupling circuitry configured to couple the first resistor to the first gate, the first voltage generator to the first resistor and ground, and the second FET in parallel with the first resistor.

In some embodiments, the circuit further comprises a third FET having a third gate, a third source, and a third drain, wherein the coupling circuitry is further configured to couple the third drain to the first drain. The circuit may further comprise a second resistor and a second voltage generator. The coupling circuitry may be further configured to couple the second resistor to the third gate and the second voltage generator. In some embodiments, the circuit further comprises a third resistor. The coupling circuitry may be further configured to couple the third resistor between the first gate and the first resistor.

The circuit may further comprise a positive voltage generator and a high gate resistor. The coupling circuitry may be further configured to couple the high gate resistor to the positive voltage generator and the first source. In some embodiments, the circuit further comprises a second resistor. The coupling circuitry may be further configured to couple the second resistor to the second gate. In some embodiments, the circuit further comprises a negative voltage generator, wherein the coupling circuitry is further configured to couple the negative voltage generator to the second resistor and ground.

In some embodiments, the circuit further comprises a first node. The second FET may be a triple-gate FET further having a third drain, a third gate, and a third source. The coupling circuitry may be further configured to couple the first resistor and the second drain to the first node and to couple the third drain to the second source. In some embodiments, the circuit further comprises a third resistor, wherein the coupling circuitry is further configured to couple the third resistor to the third gate and ground. The circuit may further comprise a fourth drain, a fourth gate, and a fourth source, wherein the coupling circuitry is further configured to couple the fourth drain to the third source.

In some embodiments, the circuit further comprises a fourth resistor, wherein the coupling circuitry is further configured to couple the fourth resistor to the fourth gate and ground. The circuit may further comprise a second node, wherein the coupling circuitry is further configured to couple the first resistor and the fourth source to the second node. In some embodiments, the circuit further comprises a second resistor, wherein the coupling circuitry is further configured to couple the first drain to the second resistor.

In some teachings, the present disclosure relates to a circuit comprising a first FET having a first gate, a first source, and a first drain, a first resistor, a triple-gate FET comprising a second drain, a second gate, and a second source, a first node, and coupling circuitry configured to couple the first resistor, the first gate, and the second drain to the first node, and the triple-gate FET in parallel with the first resistor.

In some embodiments, the circuit further comprises a second resistor, wherein the coupling circuitry is further configured to couple the second resistor to the second gate and ground. The triple-gate FET may further comprise a third drain, a third gate, and a third source, wherein the coupling circuitry is further configured to couple the third drain to the second source. In some embodiments, the circuit further comprises a third resistor, wherein the coupling circuitry is further configured to couple the third resistor to the third gate and in parallel with the second resistor.

The triple-gate FET may further comprise a fourth drain, a fourth gate, and a fourth source, wherein the coupling circuitry is further configured to couple the fourth drain to the third source. In some embodiments, the circuit further comprises a second node, wherein the coupling circuitry is further configured to couple the first resistor and the fourth source to the second node. The circuit may further comprise a third resistor, wherein the coupling circuitry is further configured to couple the third resistor to the fourth gate and in parallel with the second resistor.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1A provides an illustration of an example field-effect transistor (FET) having one or more features as described herein.

FIG. 1B provides an illustration of the example FET in an OFF state in accordance with one or more embodiments.

FIG. 1C provides an illustration of an example FET in an OFF state in which the gate of the FET is coupled to ground in accordance with one or more embodiments.

FIG. 2A illustrates a first circuit including a first (e.g., series-configured) FET, a gate resistor, and a DC voltage generator at the gate of the first FET in accordance with one or more embodiments.

FIG. 2B illustrates a second circuit in which a second FET is added across the gate resistor of the first FET in accordance with one or more embodiments.

FIG. 3A provides a simulation graph representing insertion loss performance of the FET switches described in FIGS. 2A and 2B.

FIG. 3B provides a simulation graph of isolation values of the first circuit and second circuit of FIGS. 2A and 2B, respectively.

FIG. 4A provides a simulation graph for the first switch of FIG. 2A.

FIG. 4B provides a simulation graph for the second switch of FIG. 2B.

FIG. 5A provides an illustration of an example series shunt switch having one or more features as described herein.

FIG. 5B provides an illustration of an example series shunt switch that further includes a third FET in accordance with one or more embodiments.

FIG. 6A provides a simulation graph of insertion loss values including a first insertion loss plot representing insertion loss values of the first circuit of FIG. 5A and a second insertion loss plot representing insertion loss values of the second circuit of FIG. 5B.

FIG. 6B provides a simulation graph of isolation values including a first isolation plot representing isolation values of the first circuit of FIG. 5A and a second isolation plot representing isolation values of the second circuit of FIG. 5B.

FIG. 7 provides an embodiment of a series switch circuit including a positive control voltage generator in accordance with one or more embodiments.

FIG. 8 provides an illustration of an example FET switch circuit including a triple-gate topology of an FET in accordance with one or more embodiments.

FIG. 9A provides a simulation graph showing insertion loss values related to the ON state of the circuit of FIG. 8.

FIG. 9B provides a simulation graph showing insertion loss values related to the OFF state of the circuit of FIG. 8.

FIG. 10 shows a module including some or all of a front-end architecture having one or more features as described herein.

FIG. 11 depicts an example wireless device having one or more advantageous features described herein.

### DESCRIPTION

The headings provided herein, if any, are for convenience only and do not necessarily affect the scope or meaning of the claimed invention.

Radio frequency (RF) switches may be used in various electronic devices and systems to connect and/or disconnect electrical paths between one or more poles and one or more throws. RF switches may be formed or constructed using various semiconductor-based technologies. For example, certain RF switches may be implemented using Silicon-on-Insulator (SOI) process technology, which may be advantageously utilized in certain RF circuits, including, for example, those involving high performance, low loss, high linearity switches. In such RF switching devices, performance advantages may result from building a transistor in silicon, which sits on an insulator such as an insulating buried oxide (BOX). The BOX typically sits on a handle wafer, typically silicon, but can be glass, borosilicon glass, fused quartz, sapphire, silicon carbide, or any other electrically-insulating material. Although certain embodiments are disclosed herein in the context of SOI switches, it should be understood that principles disclosed herein may be applicable with respect to other technologies as well.

Certain RF switches may be constructed at least in part of an SOI transistor, which may be viewed as a 4-terminal field-effect transistor (FET) device with gate, drain, source, and body terminals; or alternatively, as a 5-terminal device, with an addition of a substrate node. Such terminals/nodes can be biased and/or be coupled one another to, for example, improve linearity and/or loss performance of the transistor. Various examples related to SOI and/or other semiconductor devices and circuits are described herein in greater detail. Although various examples are described in the context of RF switches, and particular FET devices, it will be understood that one or more features of the present disclosure may also be applicable in other applications. References to drain or source features of FET transistors herein should be understood to be substantially interchangeable in certain embodiments. For example, while a drain node of a FET may be disclosed in an embodiment, the description associated therewith may be applicable with respect to a source node instead, or vice versa; the orientation of the FET may be substantially immaterial, or non-critical, with respect to the particular feature or principle being described.

RF switches may use switched-capacitor circuits to generate negative gate bias voltages for an “OFF,” or isolating, switch arm. Generation and/or provision of such bias voltages may be achieved using one or more clock-based switched-capacitor circuits. However, such circuits can become sources of noise, wherein clock spurs can up-convert onto the RF signal itself, or generate a higher wide-band noise floor, which may result in at least partially degraded receiver sensitivity.

In some devices, a product of the off-capacitance and on-resistance of an FET switch may be a figure of merit for processes involving the FET switch. For a given process, there may be a trade-off between insertion loss (which may be dominated by the FET on-resistance) and isolation (which may be dominated by the off-capacitance). To improve on this tradeoff, a multi-gate (e.g., double or triple) FET topology may be used in some devices to incrementally improve the on-resistance and/or off-capacitance. For narrow-band applications, resonating the off-capacitance with an inductor may improve the isolation.

When a series switch is in an OFF mode (e.g., an isolation mode), some amount of isolation may be lost due to high impedance on the gate. However, adding a second (or third) FET switch can short out the normal series gate resistor and bring the gate to ground potential for RF. Moreover, adding additional FETs can improve the isolation of the circuit. For example, high impedance of a circuit can cause performance similar to having two small capacitors from gate to drain and gate to source which provides a certain isolation, but if the gate is brought to ground, the capacitors are brought to ground and are not in the through path. The addition of a second or third FET can provide an improvement of, depending on the frequency range and size of the device, approximately 5-7 dB. The impedance of the gate may be lowered as the parasitic capacitors are brought to ground (i.e., placed in shunt) rather than being in series across the terminal source and drain of the device.

When a device is in isolation mode, the FET of the device is put into a pinch-off state, causing a high on-resistance at the FET. The isolation loss from input to output when the switch is in the OFF state may be dominated by the off-capacitance because the direct current (DC) resistance may be relatively high.

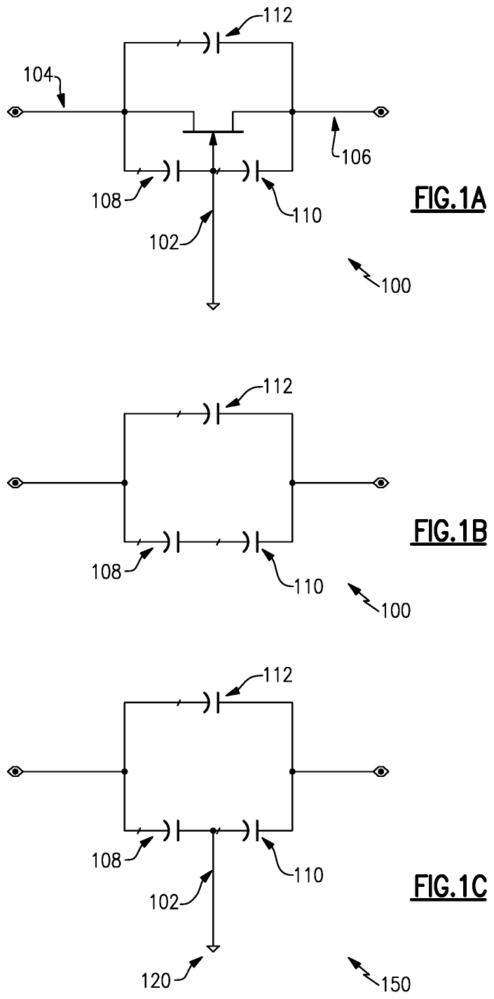

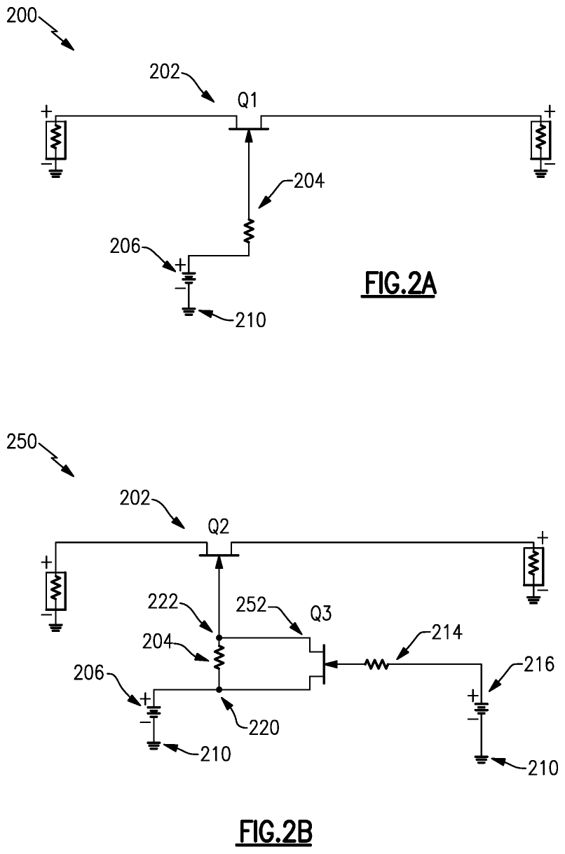

FIG. 1A provides an illustration of an example FET 100. An FET 100 has at least three terminals: a gate 102, a source 104, and a drain 106. In some cases, an FET 100 may also or alternatively include a body terminal and/or a substrate node. Due to its structure, an FET 100 may experience parasitic capacitance, which may be represented by a gate-source capacitance (Cgs) 108, a gate-drain capacitance (Cgd) 110, and a drain-source capacitance (Cds) 112.

FIG. 1B provides an illustration of the example FET 100 in an OFF state. FIG. 1C provides an illustration of an example FET 150 in an OFF state in which the gate 102 of the FET 150 is coupled to ground 120. By grounding (i.e., shorting) the FET 150, the gate-source capacitance 108 and/or gate-drain capacitance 110 of the FET 150 may be shunted and/or may be in series across drain to source of the FET 150. This configuration may improve isolation and/or may allow for a larger device with lower on-resistance and/or for improved insertion loss and isolation.

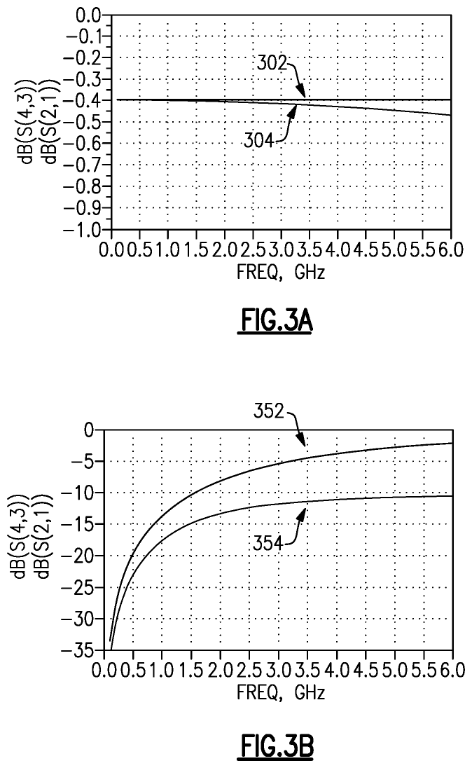

FIGS. 2A and 2B provide illustrations of example circuits including FETs. FIG. 2A illustrates a first circuit 200 including a first (e.g., series-configured) FET (“Q1” in FIG. 2A, “Q2” in FIG. 2B) 202, a gate resistor 204, and a DC voltage generator 206 at the gate of the first FET 202. In some embodiments, the voltage generator 206 may be configured to generate negative voltage. As shown in FIG. 2A, the gate resistor 204 may be coupled between the gate of the first FET 202 and the voltage generator 206. The voltage generator 206 may be coupled between the gate resistor 204 and ground 210.

FIG. 2B illustrates a second circuit 250 in which a second FET (“Q3”) 252 is added across the gate resistor 204 of the first FET 202. As shown in FIG. 2B, the second FET 252 may be situated in parallel with the gate resistor 204. The second FET 252 may be coupled to a second resistor 214 at the gate of the second FET 252. The second resistor 214 may be coupled between the gate of the second FET 252 and a second voltage generator 216. In some embodiments, the second voltage generator 216 may be configured to generate negative voltage. The second voltage generator 216 may be coupled between the second resistor 214 and ground 210. Each of the gate resistor 204, first voltage generator 206, and the source (or drain) of the second FET 252 may be coupled at a first node 220 while each of the gate of the first FET 202, the gate resistor 204, and the drain (or source) of the second FET 252 may be coupled at a second node 222.

Through addition of the second FET 252, the first FET 202 may be shorted to ground in isolation mode. By shorting the first FET 202, a gate-source capacitance and/or gate-drain capacitance of the first FET 202 may be shunted and/or may be in series across drain to source of the first FET 202. This configuration may improve isolation and/or may allow for the device to be relatively large in size while maintaining relatively low on-resistance for improved insertion loss and isolation. In low-insertion mode, there may be slightly higher loss due to the off-capacitance of the second FET 252. In some embodiments, the total gate width (“Wt”) of the second circuit 250 may be greater than the total gate width of the first circuit 200 to achieve an approximately equal insertion loss at 6 GHz as that of the first circuit 200.

Each of the first FET 202, second FET 252, and/or other FETs described with respect to other figures herein may be any type of transistor. For example, an FET described herein may be a Gallium Arsenide (GaAs) FET (GaAsFET), a metal-semiconductor FET (MESFET), a high-electron-mobility transistors (HEMT or HFET) and/or a pseudomorphic-high-electron-mobility-transistor (pHEMT), a gallium nitride (GaN) FET, and/or a complementary metal-oxide-semiconductor FET (CMOSFET).

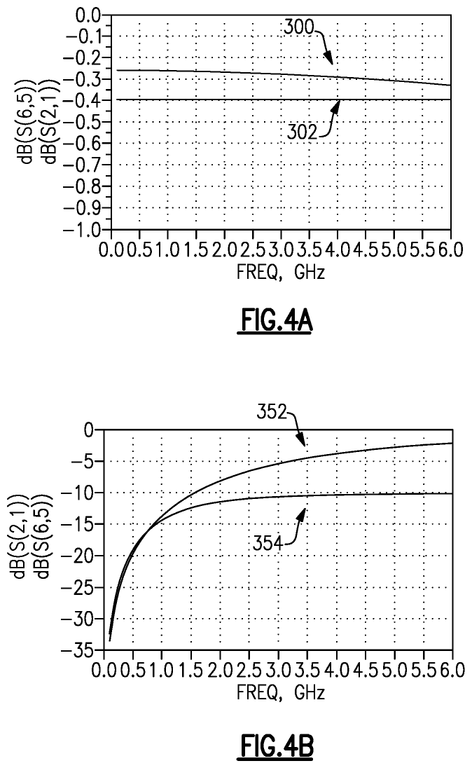

FIG. 3A provides a simulation graph representing insertion loss performance of the FET switches described in FIGS. 2A and 2B. A first insertion loss plot (“A”) 302 corresponds to the first circuit 200 of FIG. 2A and a second insertion loss plot (“B”) 304 correspond to the second circuit 250 of FIG. 2B. As shown in FIG. 3A, the second circuit 250 may have associated degradation in the loss of the circuit. Such loss may be a result of the capacitance from the second FET 252 of FIG. 2B. The degradation may be improved by using a lower capacitance for the second FET 252 when the circuit is in an OFF state, which may be accomplished by using a dual- or triple-gate FET (triple-gate configuration described with respect to FIG. 8 herein).

FIG. 3B provides a simulation graph of isolation values of the first circuit 200 and second circuit 250 of FIGS. 2A and 2B, respectively. A first isolation plot (“A”) 352 corresponds to the first circuit 200 of FIG. 2A and a second isolation plot (“B”) 354 corresponds to the second circuit 250 of FIG. 2B. As shown in FIG. 3B, the addition of the second FET 252 in FIG. 2B may advantageously provide an improvement of approximately 8 dB in isolation at 6 GHz.

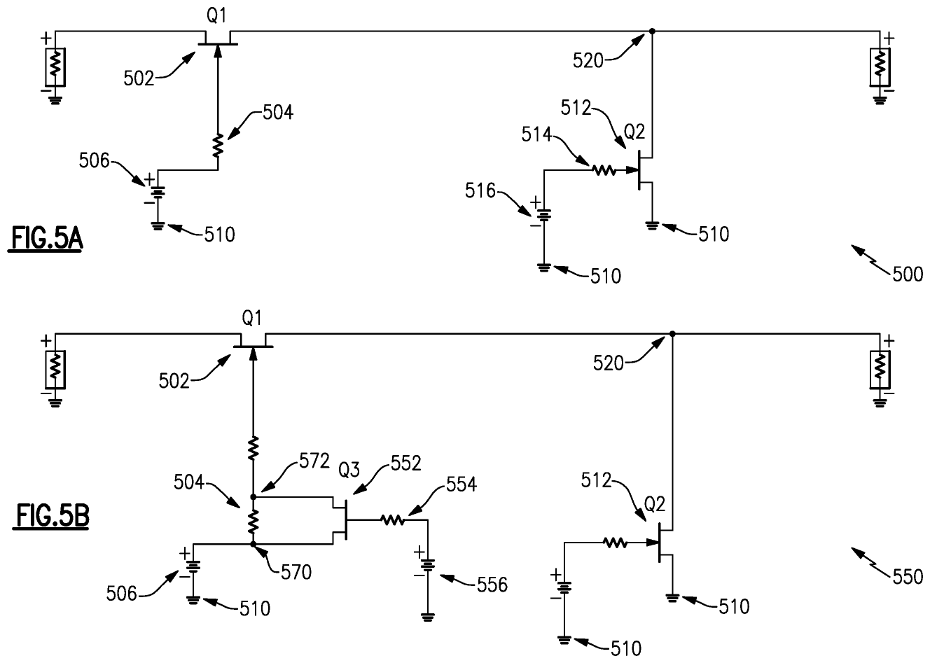

FIGS. 4A and 4B provide simulation graphs for the first switch 200 of FIG. 2A and the second switch 250 of FIG. 2B, respectively, in which the FETs (i.e., the first FET 202 and second FET 252 of FIG. 4B) have greater total gate width than in the simulations of FIGS. 3A and 3B. As shown in FIGS. 4A and 4B, second switch 250 may advantageously achieve better insertion loss and/or isolation below 6 GHz than the first switch 200 when the total gate width of the FETs is increased.

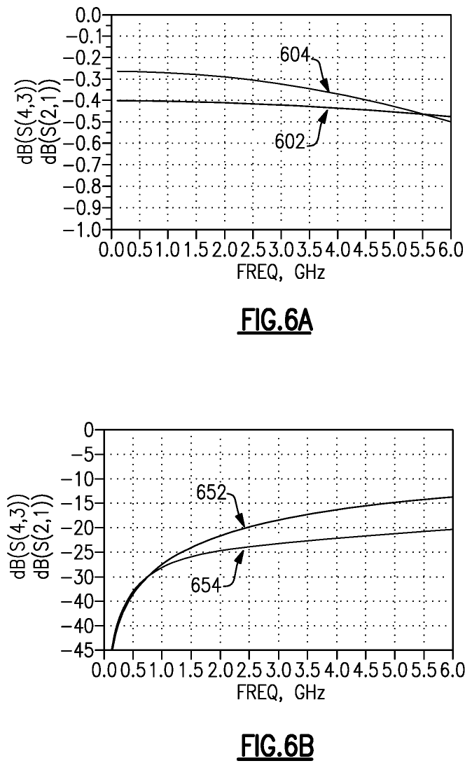

FIG. 5A provides an illustration of an example series shunt switch 500. The series shunt switch 500 includes a first FET 502 and a second FET 512. Each of the drain (or source) of the second FET 512 and the drain (or source) of the first FET 502 is coupled to a first node 520. The second FET 512 may operate as a shunt switch, while the first FET 502 may be a series switch. The gate of the first switch 502 may be coupled to a first resistor 504, which may be coupled between the first switch 502 and a first voltage generator 506. In some embodiments, the first voltage generator 506 may be configured to generate negative voltage. The first voltage generator 506 may be coupled between the first resistor 504 and ground 510. The gate of the second FET 512 may be coupled to a second resistor 514, which may be coupled between the gate of the second FET 512 and a second voltage generator 516. In some embodiments, the second voltage generator 516 may be configured to generate negative voltage. The second voltage generator 516 may be coupled between the second resistor 514 and ground 510.

FIG. 5B provides an illustration of an example series shunt switch 550 that further includes a third FET 552. In some embodiments, the third FET 552 may be situated across the first resistor 504. The third FET 552 may be situated in parallel with the first resistor 504. The gate of the third FET 552 may be coupled to a third resistor 554, which may be coupled between the gate of the third FET 552 and a third voltage generator 556. In some embodiments, the third voltage generator 556 may be configured to generate negative voltage. The third voltage generator 556 may be coupled between the third resistor 554 and ground 510. Each of the first resistor 504, first voltage generator 506, and the source (or drain) of the third FET 552 may be coupled at a second node 570 while each of the gate of the first FET 502, the first resistor 504, and the drain of the third FET 552 may be coupled at a third node 572.

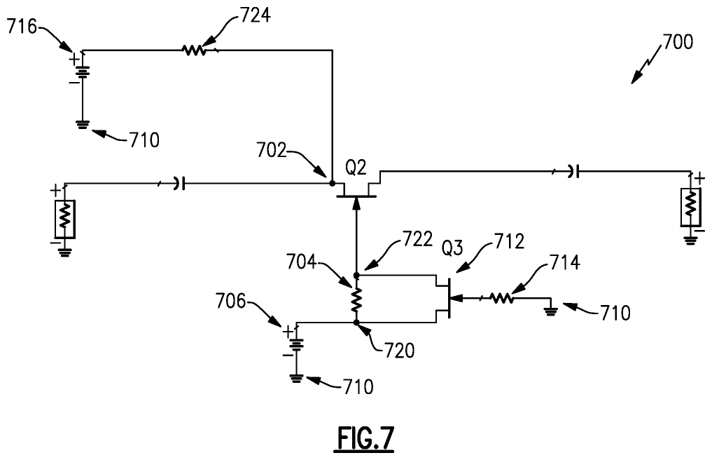

FIG. 6A provides a simulation graph of insertion loss values including a first insertion loss plot (“A”) 602 representing insertion loss values of the first circuit 500 of FIG. 5A and a second insertion loss plot (“B′”) 604 representing insertion loss values of the second circuit 550 of FIG. 5B. As shown in FIG. 6A, the insertion loss is better (e.g., higher at low frequencies) for the second circuit 550 than for the first circuit 550. This improvement in insertion loss may be due at least in part to the size increase of the second circuit 550 (e.g., adding the third FET 552 to FIG. 5B).

There is typically a tradeoff between the size of an FET and the isolation: the larger the FET is, the worse the isolation. However, by adding the third FET 522, it may advantageously be possible to achieve an improvement in isolation while also increasing insertion loss. Moreover, with increased capacitance, on-resistance may be lower.

FIG. 6B provides a simulation graph of isolation values including a first isolation plot (“A”) 652 representing isolation values of the first circuit 500 of FIG. 5A and a second isolation plot (“B′”) 654 representing isolation values of the second circuit 550 of FIG. 5B. As shown in FIG. 6B, second circuit 550 (which may have a greater total gate width than the first circuit 500) may achieve a better insertion loss and/or isolation below 5.5 GHz than the first circuit 500.

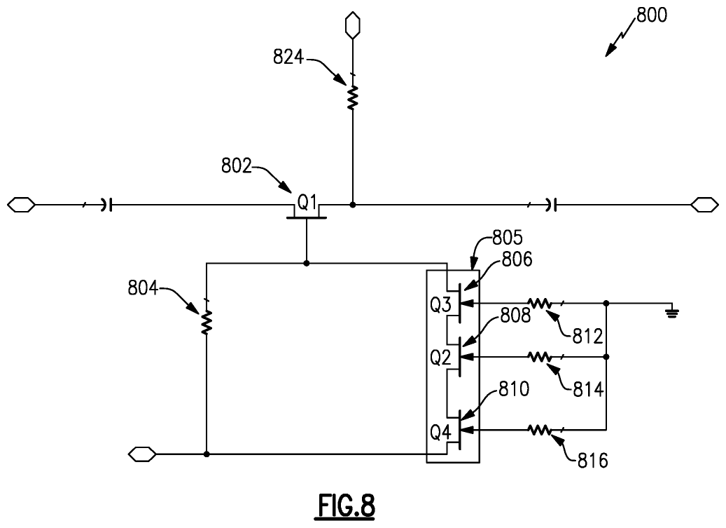

FIG. 7 provides an embodiment of a series switch circuit 700 including a positive control voltage generator 716. The first FET 702 may be in a “floating” state and/or may be controlled by the positive control voltage generator 716 to avoid negative voltage. Use of the positive control voltage generator 716 may be more practical for certain applications.

The series switch circuit 700 may include a first FET 702 and a second FET 712. The gate of the first FET 702 may be coupled to a first resistor 704, which may be coupled between the first FET 702 and a first voltage generator 706. In some embodiments, the first voltage generator 706 may be configured to generate negative voltage. The first voltage generator 706 may be coupled between the first resistor 704 and ground 710. The gate of the second FET 712 may be coupled to a second resistor 714, which may be coupled between the gate of the second FET 712 and ground 710.

In some embodiments, the second FET 712 may be situated across the first resistor 704. The second FET 712 may be situated in parallel with the first resistor 704. Each of the first resistor 504, first voltage generator 506, and the source (or drain) of the second FET 712 may be coupled at a first node 720 while each of the gate of the first FET 702, the first resistor 704, and the drain of the second FET 712 may be coupled at a second node 722.

The series switch circuit 700 may further include a high gate resistor 724 coupled to the source or drain of the first FET 702 and/or the positive control voltage generator 716. The positive control voltage generator 716 may be coupled between the high gate resistor 724 and ground 710. The high gate resistor 706 may be external to the first FET 702 and/or may have a relatively high resistance (e.g., 9 kΩ) in the ON state of the first 702. If the high gate resistor 724 does not have a relatively high resistance in the ON state, signals may be shunted to ground rather than passed across the first FET 702. The value (e.g., resistance) of the high gate resistor 724 may be changed for the OFF state. The addition of a second FET 712 may advantageously allow for changing the value of the high gate resistor 724. For example, the second FET 712 may short out the high gate resistor 724 in isolation mode. The first FET 702 and second FET 712 may have complementary logic. For example, the first FET 702 may be in an OFF state when the second FET 712 is in an ON state and the second FET 712 may be in an OFF state when the first FET is in an ON state.

FIG. 8 provides an illustration of an example FET switch circuit including triple-gate topologies of FETs that can be switched between an ON state and an OFF state. The circuit 800 may include a first FET 802 and a triple-gate FET 805. In some embodiments, the triple-gate FET 805 may be a single FET while in other embodiments, including the example shown in FIG. 8, the triple-gate FET 805 may include a second FET 806, a third FET 808, and/or a fourth FET 810 connected in series. Each of the second FET 806, third FET 808, and fourth FET 810 may have an associated gate resistor 812, 814, 816 coupled to the gate of the respective FET. The triple-gate FET 805 may have a low off-capacitance to shunt a gate resistor 804 of the first FET 802 and may improve insertion loss. Use of a triple-gate FET 805 may be more practical than single-FET designs in some applications. For example, in an ON state, any capacitance introduced from the first FET 802 may tend to increase the insertion loss due to the high impedance on the triple-gate FET 805. The drain or source of the first FET 802 may be coupled to a high gate resistor 824. In some embodiments, the resistance of the high gate resistor 824 may be relatively high (e.g., 9 kΩ). The resistor may be coupled to a voltage generator. If a single triple-gate FET 805 is used (comprising a single FET), the triple-gate FET 805 may have a relatively small size and/or low on-resistance.

The second FET 806, third FET 808, and/or fourth FET 810 may be coupled together in series. For example, the drain of the third FET 808 may be coupled to the source of the second FET 806 and the drain of the fourth FET 810 may be coupled to the source of the third FET 808.

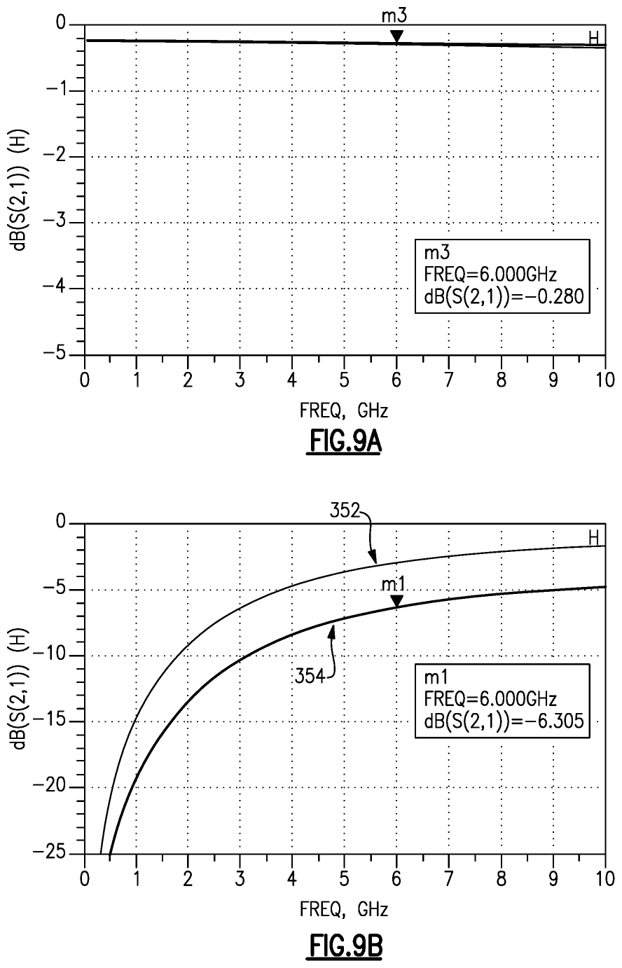

FIG. 9A provides a simulation graph showing insertion loss values related to the ON state of the circuit 800 of FIG. 8A and FIG. 9B provides a simulation graph showing insertion loss values related to the OFF state of the circuit 800 of FIG. 8. A first insertion loss plot 302 represents insertion loss values of a conventional circuit while a second insertion loss plot 304 represents insertion loss values of the circuit 800 of FIG. 8. In the OFF state, there may be approximately 3.5 dB improvement at 6 GHz for the circuit 800 compared to conventional circuits.

In some embodiments, a front-end module having one or more features as described herein can be implemented in different products, including those examples provided herein. Such products can include, or be associated with, any front-end system or module in which power amplification is desired. Such a front-end module or system can be configured to support wireless operations involving, for example, cellular devices, WLAN devices, IoT devices, etc.

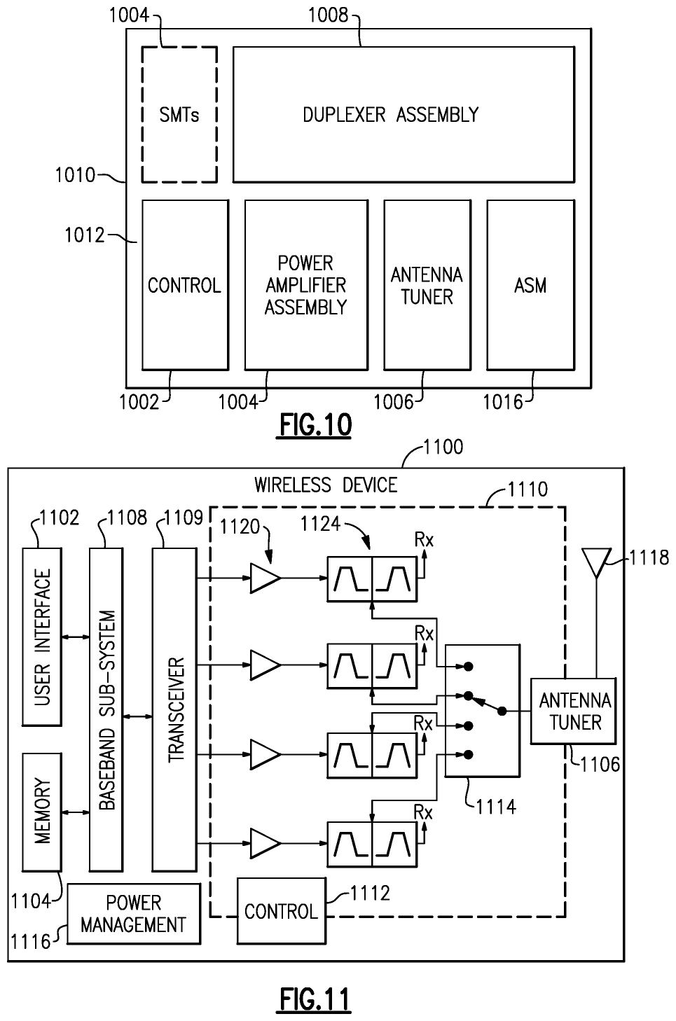

FIG. 10 shows that in some embodiments, some or all of a front-end architecture having one or more features as described herein can be implemented in a module. Such a module can be, for example, a front-end module (FEM). In the example of FIG. 10, a module 1010 can include a packaging substrate 1012, and a number of components can be mounted on such a packaging substrate. For example, a control component 1002, a power amplifier assembly 1004, an antenna tuner component 1006, and a duplexer assembly 1008 can be mounted and/or implemented on and/or within the packaging substrate 1012. Other components such as a number of SMT devices 1004 and an antenna switch module (ASM) 1016 can also be mounted on the packaging substrate 1012. Although all of the various components are depicted as being laid out on the packaging substrate 1012, it will be understood that some component(s) can be implemented over other component(s).

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

FIG. 11 depicts an example wireless device 1100 having one or more advantageous features described herein. In the context of a module having one or more features as described herein, such a module can be generally depicted by a dashed box 1110, and can be implemented as, for example, a front-end module (FEM).

Referring to FIG. 11, power amplifiers 1120 can receive their respective RF signals from a transceiver 1109 that can be configured and operated in known manners to generate RF signals to be amplified and transmitted, and to process received signals. The transceiver 1109 is shown to interact with a baseband sub-system 1108 that is configured to provide conversion between data and/or voice signals suitable for a user and RF signals suitable for the transceiver 1109. The transceiver 1109 can also be in communication with a power management component 1116 that is configured to manage power for the operation of the wireless device 1100. Such power management can also control operations of the baseband sub-system 1108 and the module 1110.

The baseband sub-system 1108 is shown to be connected to a user interface 1102 to facilitate various input and output of voice and/or data provided to and received from the user. The baseband sub-system 1108 can also be connected to a memory 1104 that is configured to store data and/or instructions to facilitate the operation of the wireless device, and/or to provide storage of information for the user.

In the example wireless device 1100, outputs of the PAs 1120 are shown to be routed to their respective duplexers 1120. Such amplified and filtered signals can be routed to an antenna 1118 through an antenna switch 1114 for transmission. In some embodiments, the duplexers 1120 can allow transmit and receive operations to be performed simultaneously using a common antenna (e.g., 1118). In FIG. 11, received signals are shown to be routed to “Rx” paths (not shown) that can include, for example, a low-noise amplifier (LNA).

As described herein, one or more features of the present disclosure can provide a number of advantages when implemented in systems such as those involving the wireless device of FIG. 11. For example, a controller 1112, which may or may not be part of the module 1110, can monitor base currents associated with at least some of the power amplifiers 1120. Based on such monitored base currents, an antenna tuner 1106 (which may or may not be part of the module 1110), can be adjusted to provide a desired impedance to the corresponding power amplifier.

### General Comments

The present disclosure describes various features, no single one of which is solely responsible for the benefits described herein. It will be understood that various features described herein may be combined, modified, or omitted, as would be apparent to one of ordinary skill. Other combinations and sub-combinations than those specifically described herein will be apparent to one of ordinary skill, and are intended to form a part of this disclosure. Various methods are described herein in connection with various flowchart steps and/or phases. It will be understood that in many cases, certain steps and/or phases may be combined together such that multiple steps and/or phases shown in the flowcharts can be performed as a single step and/or phase. Also, certain steps and/or phases can be broken into additional sub-components to be performed separately. In some instances, the order of the steps and/or phases can be rearranged and certain steps and/or phases may be omitted entirely. Also, the methods described herein are to be understood to be open-ended, such that additional steps and/or phases to those shown and described herein can also be performed.

Some aspects of the systems and methods described herein can advantageously be implemented using, for example, computer software, hardware, firmware, or any combination of computer software, hardware, and firmware. Computer software can comprise computer executable code stored in a computer readable medium (e.g., non-transitory computer readable medium) that, when executed, performs the functions described herein. In some embodiments, computer-executable code is executed by one or more general purpose computer processors. A skilled artisan will appreciate, in light of this disclosure, that any feature or function that can be implemented using software to be executed on a general purpose computer can also be implemented using a different combination of hardware, software, or firmware. For example, such a module can be implemented completely in hardware using a combination of integrated circuits. Alternatively or additionally, such a feature or function can be implemented completely or partially using specialized computers designed to perform the particular functions described herein rather than by general purpose computers.

Multiple distributed computing devices can be substituted for any one computing device described herein. In such distributed embodiments, the functions of the one computing device are distributed (e.g., over a network) such that some functions are performed on each of the distributed computing devices.

Some embodiments may be described with reference to equations, algorithms, and/or flowchart illustrations. These methods may be implemented using computer program instructions executable on one or more computers. These methods may also be implemented as computer program products either separately, or as a component of an apparatus or system. In this regard, each equation, algorithm, block, or step of a flowchart, and combinations thereof, may be implemented by hardware, firmware, and/or software including one or more computer program instructions embodied in computer-readable program code logic. As will be appreciated, any such computer program instructions may be loaded onto one or more computers, including without limitation a general purpose computer or special purpose computer, or other programmable processing apparatus to produce a machine, such that the computer program instructions which execute on the computer(s) or other programmable processing device(s) implement the functions specified in the equations, algorithms, and/or flowcharts. It will also be understood that each equation, algorithm, and/or block in flowchart illustrations, and combinations thereof, may be implemented by special purpose hardware-based computer systems which perform the specified functions or steps, or combinations of special purpose hardware and computer-readable program code logic means.

Furthermore, computer program instructions, such as embodied in computer-readable program code logic, may also be stored in a computer readable memory (e.g., a non-transitory computer readable medium) that can direct one or more computers or other programmable processing devices to function in a particular manner, such that the instructions stored in the computer-readable memory implement the function(s) specified in the block(s) of the flowchart(s). The computer program instructions may also be loaded onto one or more computers or other programmable computing devices to cause a series of operational steps to be performed on the one or more computers or other programmable computing devices to produce a computer-implemented process such that the instructions which execute on the computer or other programmable processing apparatus provide steps for implementing the functions specified in the equation(s), algorithm(s), and/or block(s) of the flowchart(s).

Some or all of the methods and tasks described herein may be performed and fully automated by a computer system. The computer system may, in some cases, include multiple distinct computers or computing devices (e.g., physical servers, workstations, storage arrays, etc.) that communicate and interoperate over a network to perform the described functions. Each such computing device typically includes a processor (or multiple processors) that executes program instructions or modules stored in a memory or other non-transitory computer-readable storage medium or device. The various functions disclosed herein may be embodied in such program instructions, although some or all of the disclosed functions may alternatively be implemented in application-specific circuitry (e.g., ASICs or FPGAs) of the computer system. Where the computer system includes multiple computing devices, these devices may, but need not, be co-located. The results of the disclosed methods and tasks may be persistently stored by transforming physical storage devices, such as solid state memory chips and/or magnetic disks, into a different state. Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Various elements may be coupled together and/or to various nodes through use of coupling circuitry. The words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A circuit comprising:
a first field-effect transistor (FET) having a first gate, a first source, and a first drain;
a first resistor;
a first voltage generator;
a second FET having a second gate, a second source, and a second drain; and
coupling circuitry configured to couple:
the first resistor to the first gate;
the first voltage generator to the first resistor and ground; and
the second FET in parallel with the first resistor.

2. The circuit of claim 1 further comprising a third FET having a third gate, a third source, and a third drain, wherein the coupling circuitry is further configured to couple the third drain to the first drain.

3. The circuit of claim 2 further comprising a second resistor and a second voltage generator, wherein the coupling circuitry is further configured to couple the second resistor to the third gate and the second voltage generator.

4. The circuit of claim 3 further comprising a third resistor, wherein the coupling circuitry is further configured to couple the third resistor between the first gate and the first resistor.

5. The circuit of claim 1 further comprising a positive voltage generator and a high gate resistor, wherein the coupling circuitry is further configured to couple the high gate resistor to the positive voltage generator and the first source.

6. The circuit of claim 1 further comprising a second resistor, wherein the coupling circuitry is further configured to couple the second resistor to the second gate.

7. The circuit of claim 6 further comprising a negative voltage generator, wherein the coupling circuitry is further configured to couple the negative voltage generator to the second resistor and ground.

8. The circuit of claim 1 further comprising a first node, wherein the second FET is a triple-gate FET further having a third drain, a third gate, and a third source, and wherein the coupling circuitry is further configured to couple the first resistor and the second drain to the first node and to couple the third drain to the second source.

9. The circuit of claim 8 further comprising a third resistor, wherein the coupling circuitry is further configured to couple the third resistor to the third gate and ground.

10. The circuit of claim 8 further comprising a fourth drain, a fourth gate, and a fourth source, wherein the coupling circuitry is further configured to couple the fourth drain to the third source.

11. The circuit of claim 10 further comprising a fourth resistor, wherein the coupling circuitry is further configured to couple the fourth resistor to the fourth gate and ground.

12. The circuit of claim 10 further comprising a second node, wherein the coupling circuitry is further configured to couple the first resistor and the fourth source to the second node.

13. The circuit of claim 1 further comprising a second resistor, wherein the coupling circuitry is further configured to couple the first drain to the second resistor.

14. A circuit comprising:
a first field-effect transistor (FET) having a first gate, a first source, and a first drain;
a first resistor;
a triple-gate FET comprising a second drain, a second gate, and a second source;
a first node; and
coupling circuitry configured to couple:
the first resistor, the first gate, and the second drain to the first node; and
the triple-gate FET in parallel with the first resistor.

15. The circuit of claim 14 further comprising a second resistor, wherein the coupling circuitry is further configured to couple the second resistor to the second gate and ground.

16. The circuit of claim 15 wherein the triple-gate FET further comprises a third drain, a third gate, and a third source, wherein the coupling circuitry is further configured to couple the third drain to the second source.

17. The circuit of claim 16 further comprising a third resistor, wherein the coupling circuitry is further configured to couple the third resistor to the third gate and in parallel with the second resistor.

18. The circuit of claim 16 wherein the triple-gate FET further comprises a fourth drain, a fourth gate, and a fourth source, wherein the coupling circuitry is further configured to couple the fourth drain to the third source.

19. The circuit of claim 18 further comprising a second node, wherein the coupling circuitry is further configured to couple the first resistor and the fourth source to the second node.

20. The circuit of claim 18 further comprising a third resistor, wherein the coupling circuitry is further configured to couple the third resistor to the fourth gate and in parallel with the second resistor.
